(19) United States
(12) Patent Application Publication
(10) Pub. No.: US 2014/0322853 A1
(43) Pub. Date: Oct. 30, 2014

(54) Novel Zwitterionic Polyelectrolytes as Efficient Interface Materials for Application in Optoelectronic Devices

(71) Applicant: Advent Technologies Inc., East Hartford, CT (US)

(72) Inventors: Christos L. Chochos, Patras (GR); Vasilis G. Gregoriou, East Hartford, CT (US)

(73) Assignee: Advent Technologies Inc., East Hartford, CT (US)

(21) Appl. No.: 14/261,617

(22) Filed: Apr. 25, 2014

Related U.S. Application Data
(60) Provisional application No. 61/815,788, filed on Apr. 25, 2013.

(51) Int. Cl. C08G 75/24; H01L 51/00; C08G 75/06

(52) U.S. Cl. CPC C08G 75/24; C08G 75/06; H01L 51/0002
USPC 438/46; 525/417; 438/82

(57) ABSTRACT

Facile ways towards the development of linear and brush-type zwitterionic conjugated polyelectrolytes possessing hole or electron blocking abilities are presented using combination of polymerization techniques, such as Suzuki or Stille cross coupling, Grignard Metathesis Polymerization and Atom transfer radical polymerization. These zwitterionic conjugated polyelectrolytes will serve as excellent interface materials in various optoelectronic devices.

### CROSS REFERENCE TO RELATED PATENT APPLICATIONS

This patent application claims a benefit to the filing date of U.S. Provisional Patent Application Ser. No. 61/858,788 titled “Novel Zwitterionic Polyelectrolytes as Efficient Interface Materials for Application in Optoelectronics Devices” that was filed on Apr. 25, 2013. The disclosure of U.S. 61/858,788 is incorporated by reference herein in its entirety.

### FIELD OF INVENTION

This invention is related to the development of new zwitterionic conjugated polyelectrolytes bearing in the main chain either electron rich compounds such as thiophene, dithieno[3,2-b:2′,3′-d]silole and benzo[1,2-b:4,5-b′]dithiophene or electron deficient building blocks such as quinoxaline and 2H-benzimidazole and cationic and anionic polar groups as side chain pendants. These zwitterionic conjugated polyelectrolytes will prevent the motion of the counter ions, therefore will serve as excellent interface materials in various optoelectronic applications.

### BACKGROUND INFORMATION

Organic electronics have been heavily studied in the past two decades because they exhibit mechanical flexibility and versatile chemical design and synthesis, and are inexpensive, lightweight and can easily be processed. Devices including organic light emitting diodes (OLEDs), photovoltaics (OPVs)—solar cells and photodetectors, field-effect transistors (OFETs), memory and biochemical sensors have all been demonstrated. OLEDs, developed for applications in flat panel displays and solid-state lighting, can be already found in consumer electronic products, such as car stereos, cell phones, and other appliances. Organic thin film transistors (OTFTs) are being developed for applications in display backplanes and disposable electronics, such as sensor arrays, smart cards (addressable identification (ID) and vending cards), and radio-frequency identification (RFID) tags. Organic electronics might also be very applicable to PV technology, which has been increasingly recognized as part of the solution to the growing energy challenges and can be an integral component of future global energy production. The performance and lifetime of organic electronic devices are critically dependent on the properties of both the active materials and their interfaces. In these devices, metal electrodes are utilized to inject charge into (or extract charge from) the organic semiconductor layer(s).

Therefore, control over the interface between organic semiconductor and inorganic electrode/dielectric is essential. This can range from simple wettability or adhesion between different materials to direct Modification of the electronic structure of the material (Friend, Gymer et al. 1999; Tang 1986). Conjugated polyelectrolytes (both neutral and cationic; CPEs) came in the focus of interest since the first demonstration of their potential as effective interface layers, especially electron-injecting layers (Seo, Gutacker et al. 2009). In OPVs for example the interface between the active layer and the electrodes should be ohmic in order to minimize the contact resistance. Such a requirement has led to efforts in interfacial engineering, including the use of thermally deposited LiF or bathocuproine (BCP), self-assembled monolayers (SAMs), metal oxides (i.e., TiOₓ, CsCO₃, MoO₃, and ZnO) and CPEs (He, Zhong et al. 2011). Among the proposed approaches, integration of CPEs as interface layer leads to significant improvement of the device performance (Seo, Gutacker et al. 2011). By simply incorporating thin layers of the neutral CPEs P1 or the cationic CPEs P2 (FIG. 1) as the cathode interlayer in OPVs consisting of the high performance PTB7:PC₇₁BM and PCDTBT:PC₇₁BM systems as the active layers lead to increased PCEs of 8.37% (record efficiency) and 6.5%, respectively (Seo, Gutacker et al. 2011). For comparison reasons, the PCEs of the PTB7:PC₇₁BM and PCDTBT:PC₇₁BM based solar cells without the use of the CPEs as the interface layers are 7.4% and 5%, respectively. The drastic increase in the PCEs was achieved by the simultaneous enhancement in the open-circuit voltage, short-circuit current density, and fill factor. The improved charge-injection and extraction ability of these compounds may result from a combination of two or more effects, including 1) charge accumulation at interfaces and 2) formation of permanent dipoles at the organic/metal interface towards the low-work function metal electrode, thus facilitating efficient electron injection and extraction to or from the organic layer. Except from the previous advantages these CPEs due to their solubility in polar solvents (such as methanol) and insolubility in nonpolar solvents (aromatic solvents) allow for a so-called orthogonal processing of multilayer devices by “wet-processing” techniques.

One main feature but also possible disadvantage in the application of such cationic CPE layers in electronic devices is the presence of mobile counter ions (here anions). Even though, the motion of fluoride counter ions can be used to create p-n junctions in combination with fluoride-accepting functions in double-layer (heterojunction) devices (Hoven, Wang et al. 2010), the motion of the counter ions most of the times causes problems, especially in OLED and OFET devices, because of the creation of unwanted space charges. To circumvent this problem, a very elegant solution is the formation of a zwitterionic CPE by the replacement of small and mobile anions of the cationic CPE (such as fluoride, chloride, or bromide) by the direct “attach” of the counter anions to the immobile, cationic CPE main chain (Fang, Wallikewitz, et al. 2011). At this point it should be clarified that polyelectrolytes contain anionic or cationic groups, while polyzwitterions contain both anionic and cationic groups.

The state of the art zwitterionic conjugated polyelectrolytes (ZCPEs) that have been applied in electronic devices as interface layers are the polyfluorene-based derivatives of FIG. 2. The application of these zwitterionic polyfluorenes as an electron-injection layer in polymer-based OLED devices led to impressive improvements of the device performance. The OLED devices showed short response times of <10 ms using a polyfluorene derivative as a green emitter and an impressive maximum luminance efficiency of up to 23.8 CdA⁻¹ for a PPV derivative as a green emitter (Duan, Wang et al. 2011), indicating that the pinned counter anions are fully immobilized. Finally, except from the polyfluorene-based ZCPEs presented in FIG. 2 only few examples of other ZCPEs based on polythiophene derivatives have been developed in the past (Andersson, Ekeblad et al. 1991) but the research was focused mainly on sensor applications and has not been extended in electronic devices.

### SUMMARY OF THE INVENTION

Zwitterionic polyelectrolytes (ZCPEs) combine the optoelectronic properties of organic semiconductors with the ability of polyelectrolytes to have their function determined by electrostatic forces. These polymers are of great interest because they couple the optoelectronic/redox properties due to the conjugated backbone with solubility in polar solvents and processability owing to the anionic and cationic solubilizing groups. Most importantly though, one of their major advantage is the absence of mobile counter-ions among the side chains as compared to that of common conjugated polyelectrolytes (CPEs) which combine charged side chains with mobile counterions such as Na⁺, Br⁻, and tetrasubstituted borates such as BPh₄⁻ and BIm₄⁻, that can migrate during device operation and lead to long turn-on times and redistribution of the internal field when applied in various electronic devices. Moreover, their solubility in polar solvents (such as methanol) and insolubility in nonpolar solvents (aromatic solvents) allow for a so-called orthogonal processing of multilayer devices by “wet-processing” techniques. After the active semiconducting layer is spin-coated from organic solvents such as toluene, chlorobenzene, or 1,2-dichlorobenzene, the electron-injection layer can be processed from a polar solvent without redissolution of the already deposited layer. Alternatively, in devices with an inverted sequence of the layers the semiconductive layer can be deposited on top of the ZCPE-based injection layer. Up to now, ZCPEs are based only on linear polyfluorene or polythiophene derivatives. To the best of our knowledge there are no reports in the open literature for lower band gaps (LBG) and different polymeric architecture ZCPEs. In this project, we would like to expand this field by developing new electron and hole blocking ZCPEs possessing different polymeric architectures. Linear and brush-type ZCPEs containing dithieno[3,2-b:2′,3′-d]silole, benzo[1,2-b:4,5-b′]dithiophene, quinoxaline and 2H-benzimidazole as the conjugated main chain and tertiary amino functions into zwitterionic sulfobetaine will be developed using a combination of modern synthetic methodologies like: (i) Grignard Metathesis and Stille cross-coupling polymerization, (ii) Atom Transfer Radical Polymerization (ATRP) and (iii) click chemistry.

### BRIEF DESCRIPTION OF THE DRAWINGS

FIG. 1 illustrates the structure of various electrolytes.

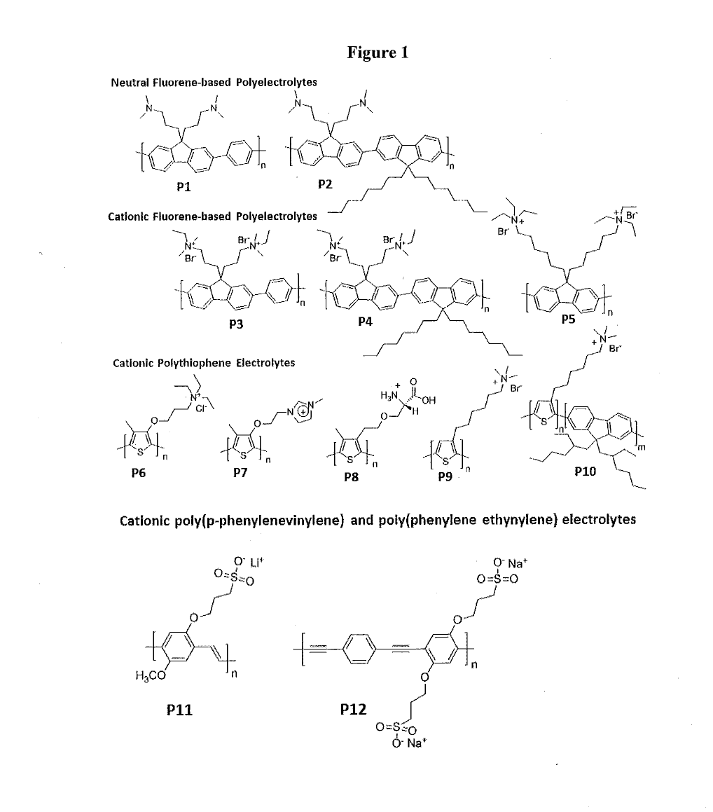

FIG. 2 illustrates the structure of zwitterionic fluorine-based polyelectrolytes.

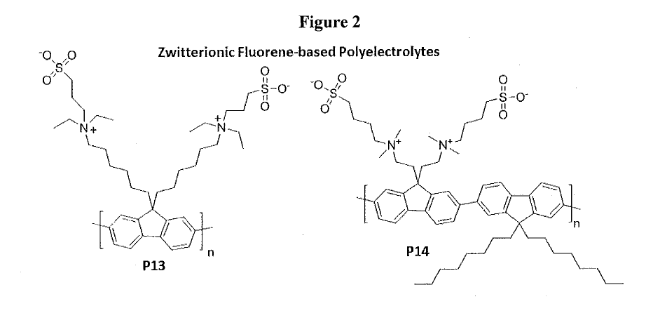

FIG. 3 illustrates an optoelectronic device for use with the polyelectrolytes disclosed herein.

### DETAILED DESCRIPTION OF THE INVENTION

The present invention relates to the development of new zwitterionic conjugated polyelectrolytes (structures 1-6) comprising linear and brush type copolymers bearing thiophene, benzo[1,2-b:4,5-b′]dithiophene or dithieno[3,2-b:2′,3′-d]silole moieties and new electron transporting zwitterionic conjugated polyelectrolytes (structures 7-10) comprising linear and brush type copolymers bearing 2H-benzimidazole or quinoxaline moieties. The structures of the materials are given below.

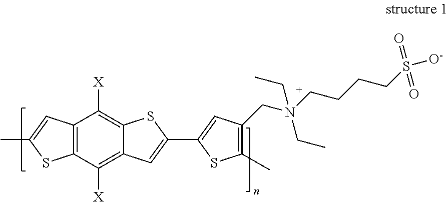

wherein X can be the same or different and is selected from the group consisting of: X=alkyl, alkoxy,

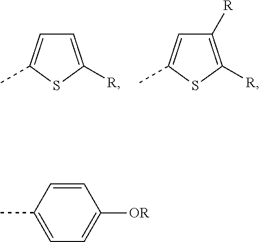

and R: —CₙH₂ₙ₊₁, n>1; linear or branch

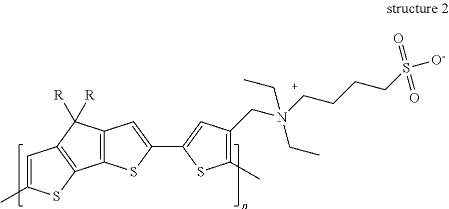

wherein R can be the same or different and is selected from the group consisting of: R: —CₙH₂ₙ₊₁, n>1; linear or branch

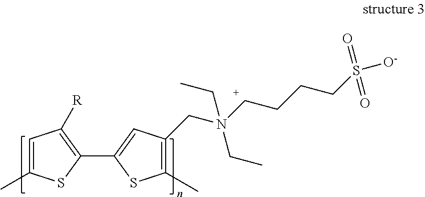

wherein R can be the same or different and is selected from the group consisting of: R: —CₙH₂ₙ₊₁, n>1; linear or branch

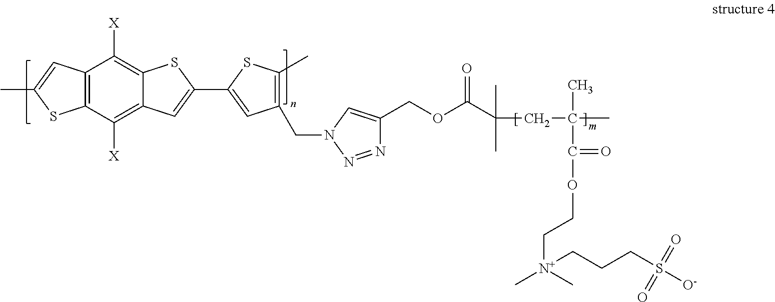

wherein X can be the same or different and is selected from the group consisting of: X=alkyl, alkoxy,

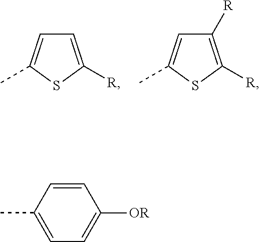

and R: —CₙH₂ₙ₊₁, n>1; linear or branch

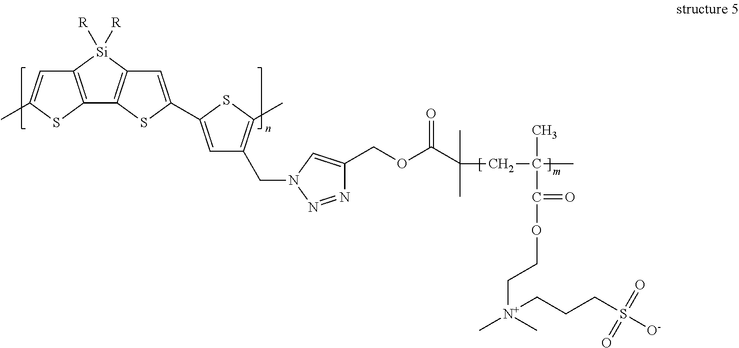

wherein R can be the same or different and is selected from the group consisting of: R: —CₙH₂ₙ₊₁, n>1; linear or branch

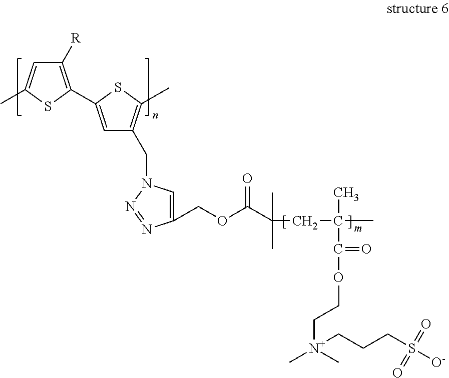

wherein R can be the same or different and is selected from the group consisting of: R: —CₙH₂ₙ₊₁, n>1; linear or branch

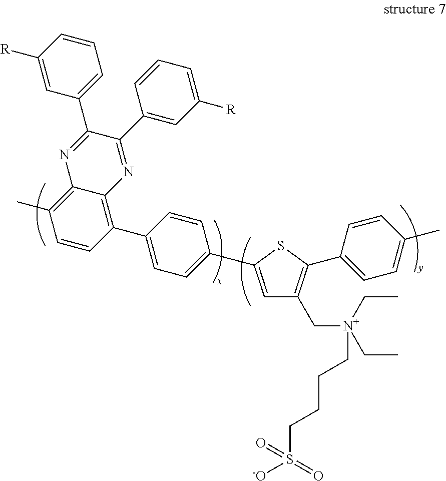

wherein R can be the same or different and is selected from the group consisting of: R: —CₙH₂ₙ₊₁, n>1; linear or branch; or alkoxy

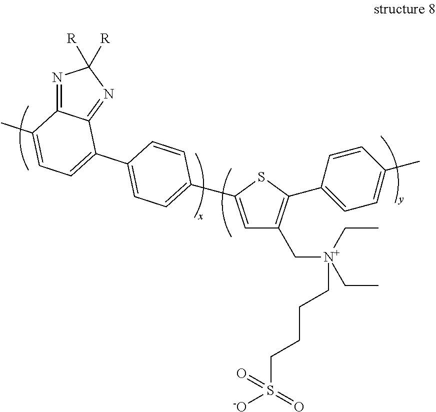

wherein R can be the same or different and is selected from the group consisting of: R: —CₙH₂ₙ₊₁, n>1; linear or branch; or alkoxy

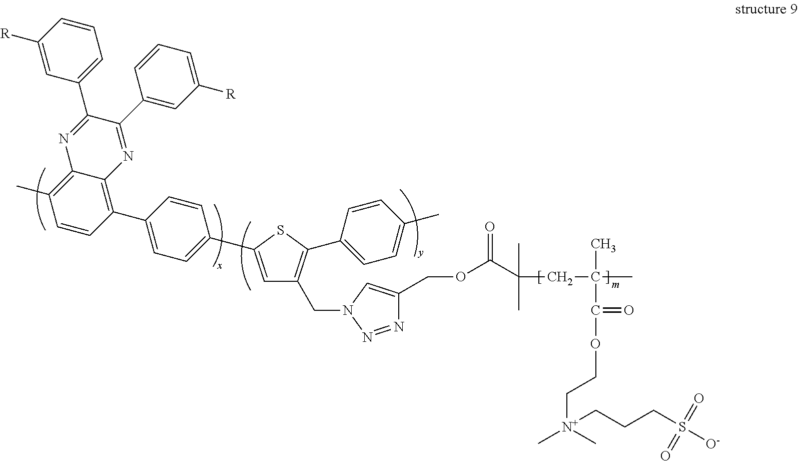

wherein R can be the same or different and is selected from the group consisting of: R: —CₙH₂ₙ₊₁, n>1; linear or branch; or alkoxy

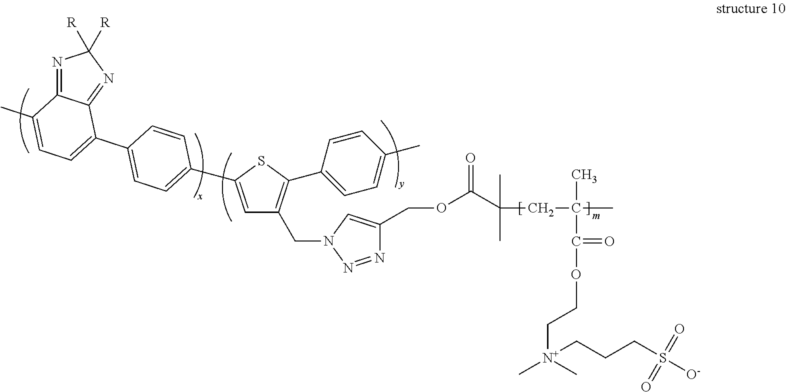

wherein R can be the same or different and is selected from the group consisting of: R: —CₙH₂ₙ₊, n>1; linear or branch; or alkoxy

The following non-limiting examples are illustrative of the invention. All documents mentioned herein are incorporated herein by reference.

### Example 1

### Synthesis of Linear Electron Blocking ZCPES (Structures 1-3)

Common organic chemistry reactions for the synthesis of the functional monomers M1-M4 (Scheme 1). The key intermediate building block is the 2,5-dibroino-3-((diethylamine)methyl)thiophene M4. The synthesis of M4 starts with the reaction of the commercially available 3-thiophene methanol with bromine to obtain M3 and then subsequent reaction with diethylamine to yield M4. The distannyl functionalized monomers M1 and M2 can be synthesized by addition of trimethyltin chloride and butyl lithium to benzo[1,2-b:4,5-b]dithiophene and dithieno[3,2-b:2′,3′-d]silole, respectively.

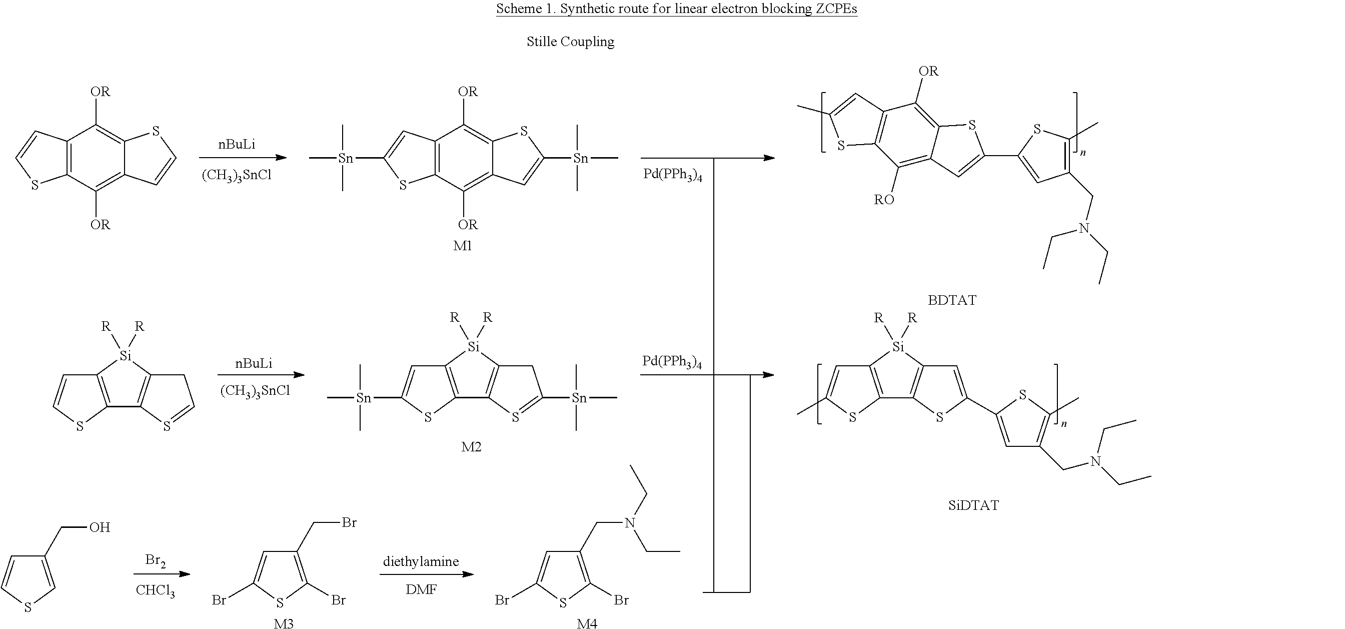

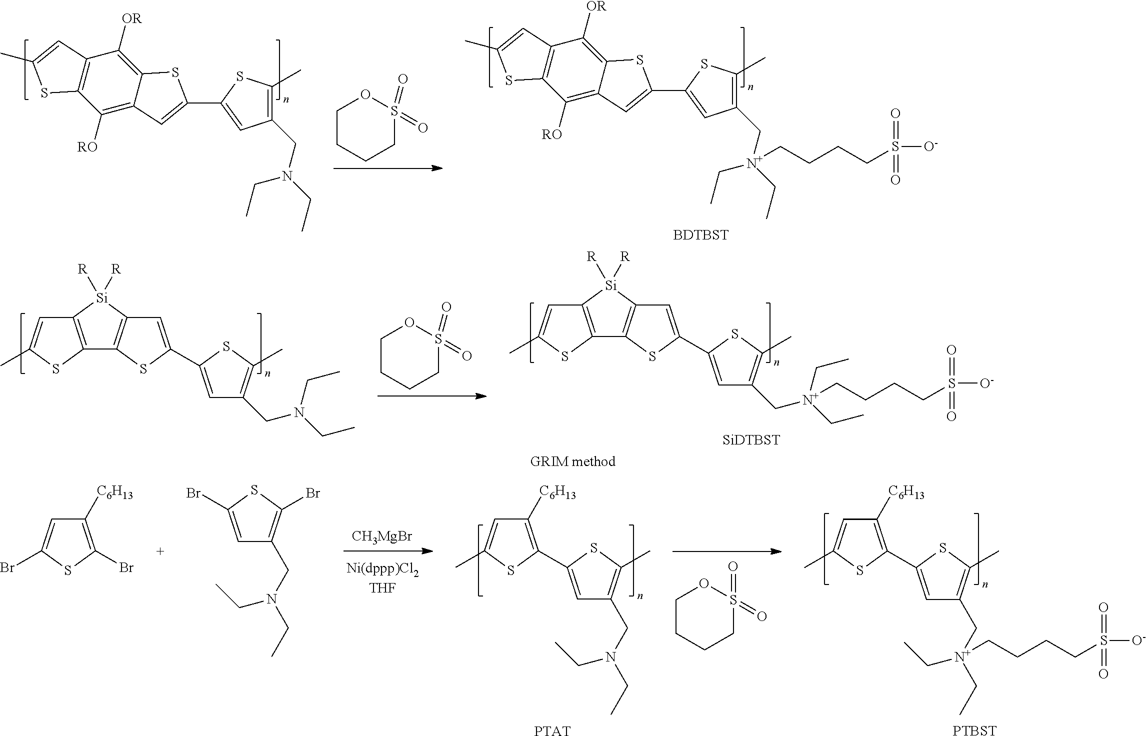

Stille cross-coupling polymerization reaction between the distannyl functionalized monomers M1 and M2 with M4 by using Palladium catalysts, for example tetrakis(triphenylphosphine)palladium(0) [Pd(PPh₃)₄] or tris(dibenzylideneacetone)dipalladium(0) [Pd₂(dba)₃] for the synthesis of the precursor polymers BDTAT and SiDTAT, respectively.

Grignard metathesis polymerization conditions (addition of a Grignard reagent and a Nickel catalyst [1,3-Bis(diphenylphosphino)propane]dichloronickel(II); Ni(dppp)Cl₂) in a mixture of 2,5-dibromo 3-hexylthiophene and M4 will provide the regioregular neutral polythiophene precursor PTAT.

The direct “attachment” of the counter anions to the immobile, cationic CPE main chain of PTAT, BDTAT and SiDTAT will be accomplished in a very simple, straightforward way, according to a modified literature procedure (Duan, Wang et al. 2011; Fang, Wallikewitz et al. 2011).

Starting from the neutral PTAT, BDTAT and SiDTAT precursors, a one-step reaction with cyclic 1,4-butane sultone directly yields the zwitterionic target linear polymers, PTBST, BDTBST and SiDTBST. The zwitterionic sulfobetaine side groups will be formed under relatively mild reaction conditions.

### Example 2

### Synthesis of Brush-Type Electron Blocking ZCPEs (Structures 4-6)

The ever more demanding requirements for novel polymeric materials raise the necessity to be able to combine all kinds of polymers in an easy manner. To overcome this challenge, polymer chemists have explored a variety of approaches to combine different polymer chains. In addition, the combination of synthetic organic chemistry and polymer chemistry is a very promising approach to build novel structures by coupling preformed polymers, which allows the combination of the state-of-the-art in living/controlled polymer chemistry with the best known organic coupling procedures. In this respect, the concept of click chemistry seems to be the ideal method to couple preformed polymer structures. Click chemistry comprises the metal catalyzed azide/alkyne ‘click’ reaction (a variation of the Huisgen 1,3-dipolar cycloaddition reaction between terminal acetylenes and azides).

Side-chain modified conjugated polymers synthesized by Stille cross-coupling or GRIM method with pendant azido moieties for the generation of brush-polymers will be initially prepared (Scheme 2). In parallel, homopolymers of 2-(dimethylamino)ethyl methacrylate will be synthesized by Atom Transfer Radical Polymerization (ATRP) using an alkyne-functionalized initiator. ATRP is the most extensively studied controlled/living radical polymerization (CRP) method, due to its simplicity and broad applicability, predetermined molecular weight, designed molecular weight distribution, controlled topology, composition and functionality. Then, the tertiary amino functions of the poly(2-(dimethylamino)ethyl methacrylate) will be transformed into zwitterionic sulfobetaine by addition of cyclic 1,3-propane sultone. Finally, the novel brush-type polythiophene and LBG ZCPEs will be prepared by the click reaction between the end alkyne-functionalized zwitterionic poly(2-(dimethylamino)ethyl methacrylate) sulfobetaine with the azido side-chain modified conjugated polymers.

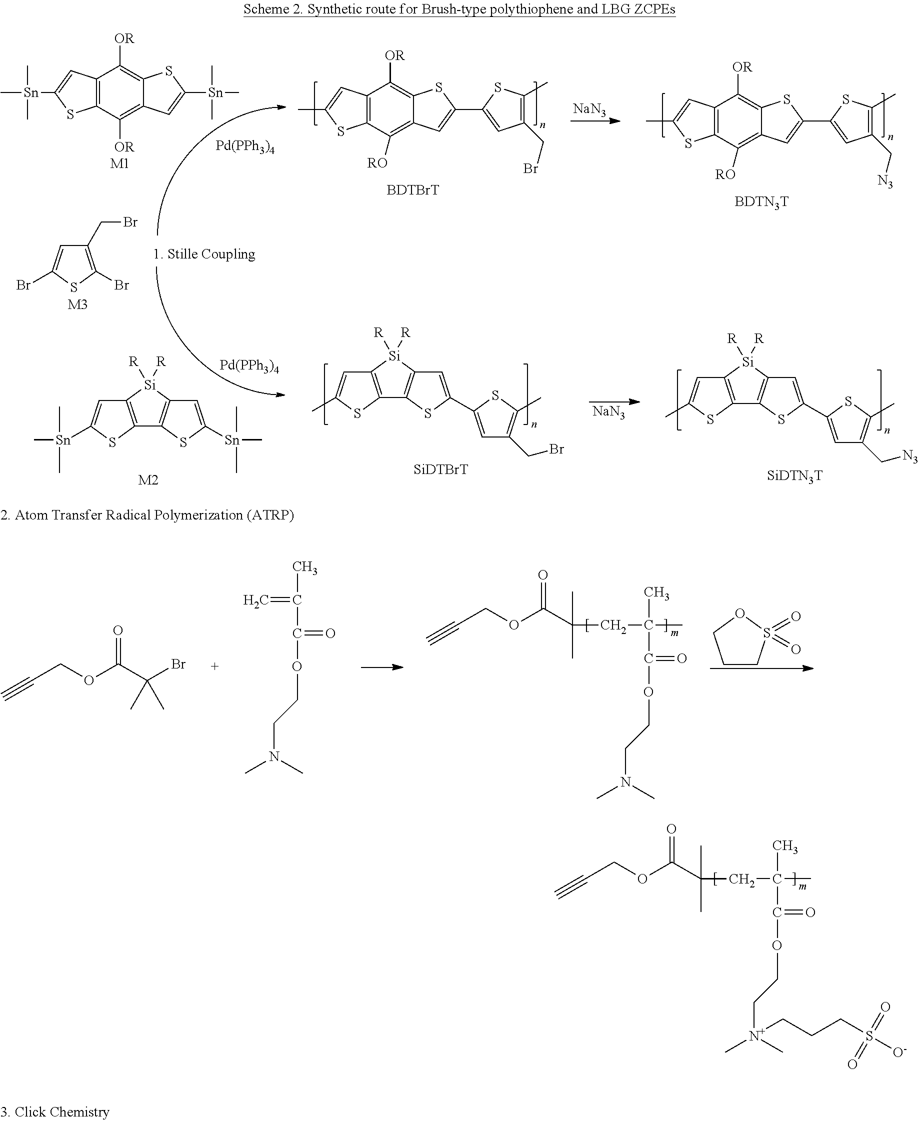

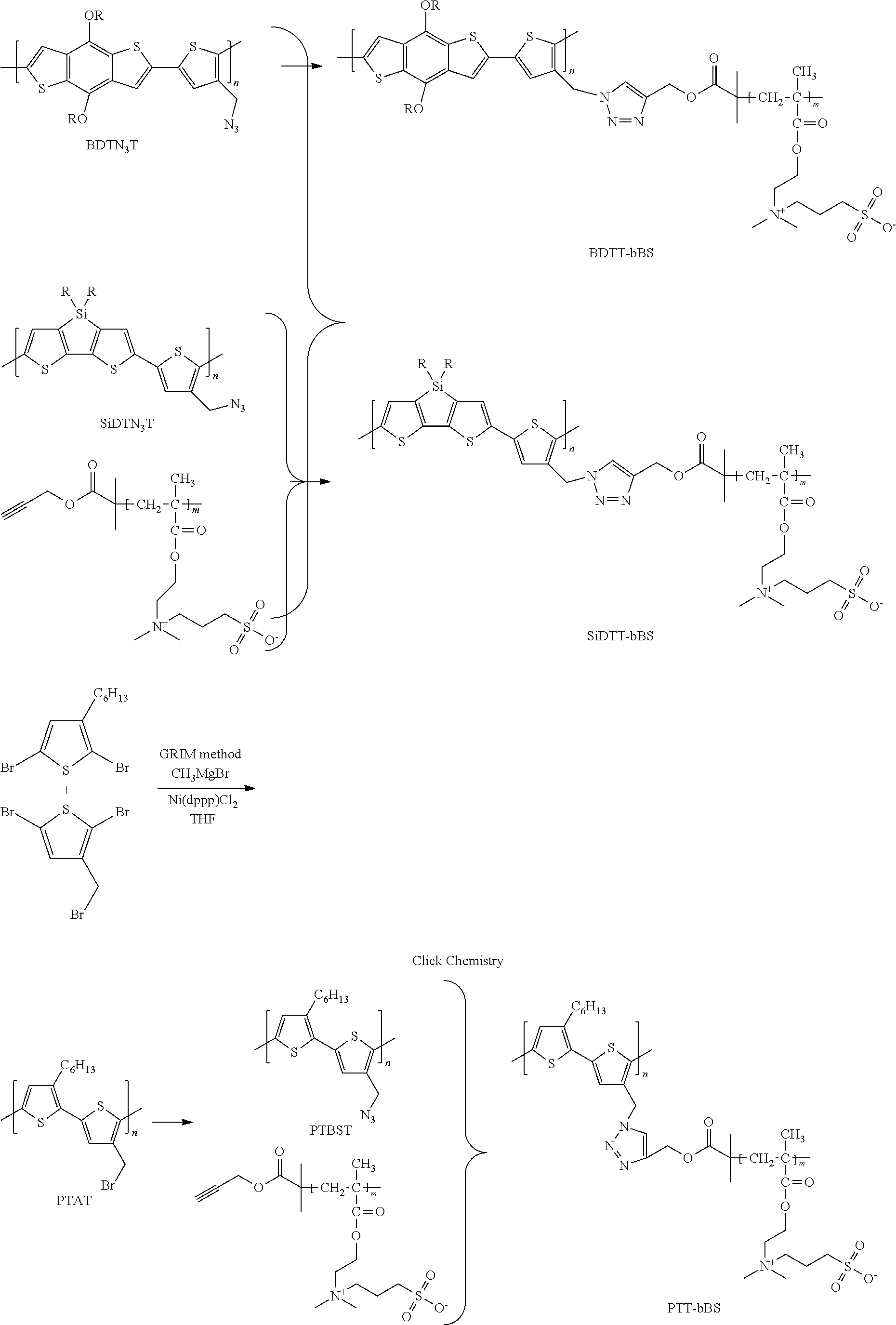

### Example 3

### Synthesis of Linear Hole Blocking ZCPES (Structures 7-8)

Reduction of 4,7-dibromo-[2,1,3]benzothiadiazole with NaBH₄ provide 1,2-diamine-3,6-dibromo benzene (Neophytou, Ioannidou et al. 2012) that will be condensed with appropriate 1,2-dicarbonyl or keto-derivatives to give the corresponding quinoxaline M5 and 2H-benzimidazole M6 (Scheme 3). Stille cross-coupling polymerization reaction between the distannyl phenyl ring, M4 and either M5 Or M6 by using Palladium catalysts, for example tetrakis(triphenylphosphine)palladium(0) [Pd(PPh₃)₄] or tris(dibenzylideneacetone)dipalladium(0) [Pd₂(dba)₃] for the synthesis of the precursor polymers PhQXAT and PhBzImAT and subsequently, a one-step reaction with cyclic 1,4-butane sultone directly yields the zwitterionic target linear polymers, PhQXBST and PhBzImBST. The zwitterionic sulfobetaine side groups will be formed under relatively mild reaction conditions.

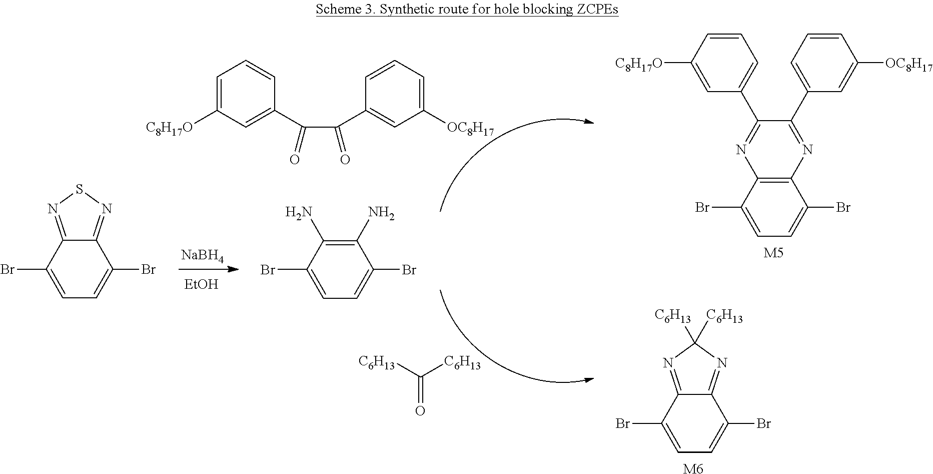

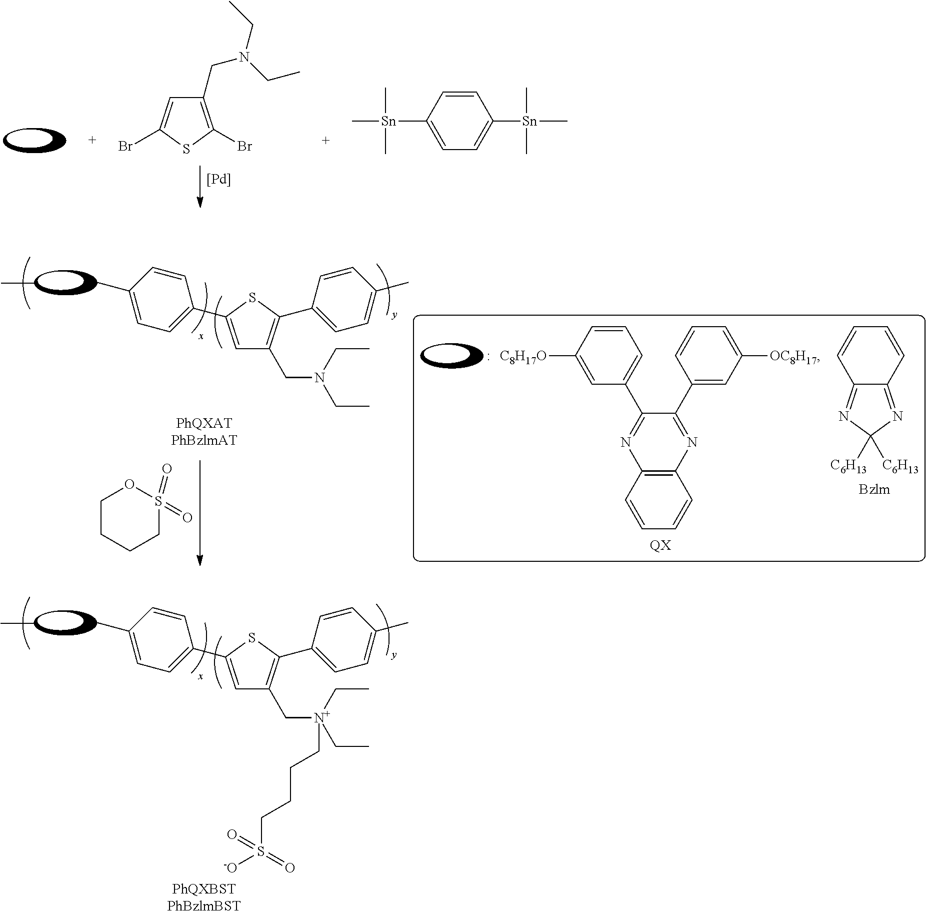

### Example 4

### Synthesis of Brush-Type Hole Blocking ZCPEs (Structures 9-10)

Side-chain modified phenyl-type conjugated polymers consisting of bromomethyl substituted thiophene ring and either quinoxaline or 2H-benzimidazole moieties synthesized by Stille cross-coupling (Scheme 4). Then, subsequent transformation of the bromomethyl groups to pendant azido moieties (PhQXTN3 and PhBzImTN3) for the generation of brush-polymers will be performed. Finally, the novel brush-type hole blocking ZCPEs (PhQXT-bBS and PhBzImT-bBS) will be prepared by the click reaction between the end alkyne-functionalized zwitterionic poly(2-(dimethylamino)ethyl methacrylate) sulfobetaine with the azido side-chain modified conjugated polymers.

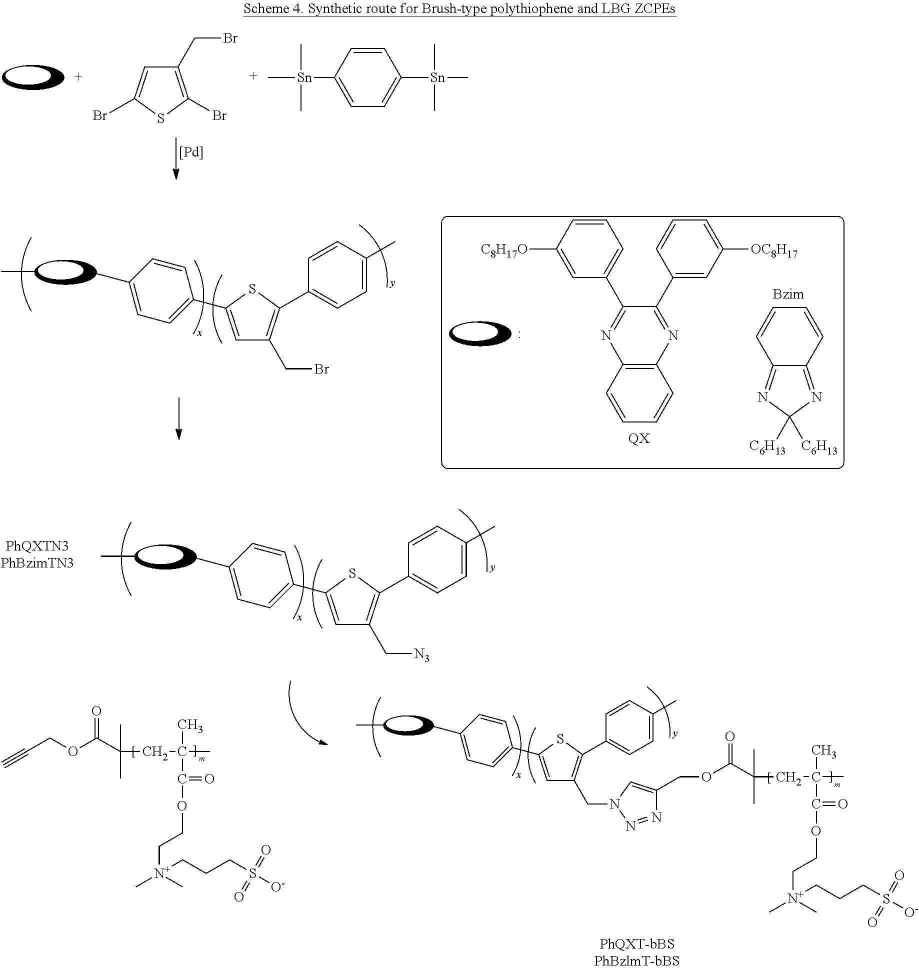

Polymers 1-10 will be evaluated in single cell polymer-fullerene BHJ solar cells both in normal and inverted structure. The big advantage of BHJ cells is their simple processing. All active layers can be processed from solution which includes spin coating, doctor blade, spray coating as well as roll to roll. Our BHJ solar cell activities will focus on the optimization of the wet processing processes.

### Photovoltaic Device Fabrication

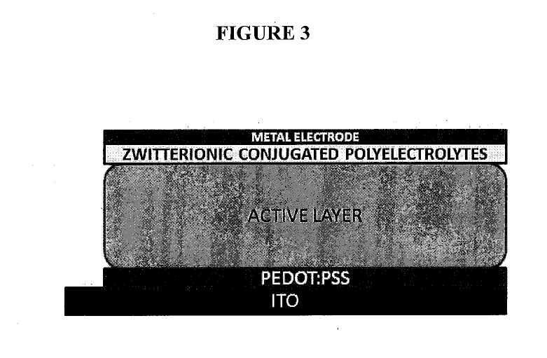

Single layer organic photovoltaic cells are made by sandwiching a layer of organic electronic materials (regioregular poly(3-hexylthiophene, low band gap conjugated polymers provided from different chemical suppliers and fullerene derivatives such as PCBM) between two metallic conductors, typically a layer of indium tin oxide (ITO) with high work function and a layer of low work function metal such as silver (Ag), gold (Au) or aluminium (Al). Our ZCPEs will be used as interlayers between the active layer and the electrodes to help charge extraction. The ZCPEs of structures 1-10 will be used in optoelectronic devices having the structure illustrated in FIG. 3.

What is claimed is:

1. Conjugated polyelectrolytes comprising the general structural formulas: 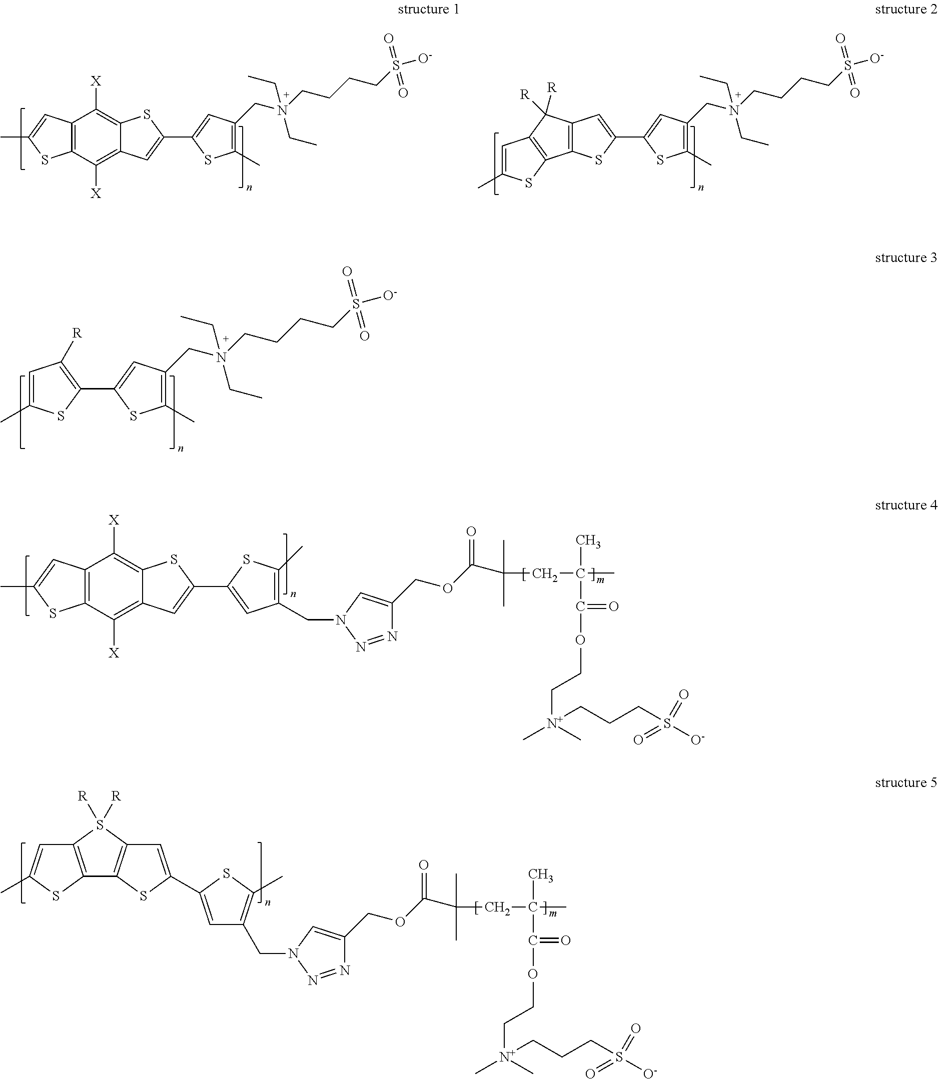 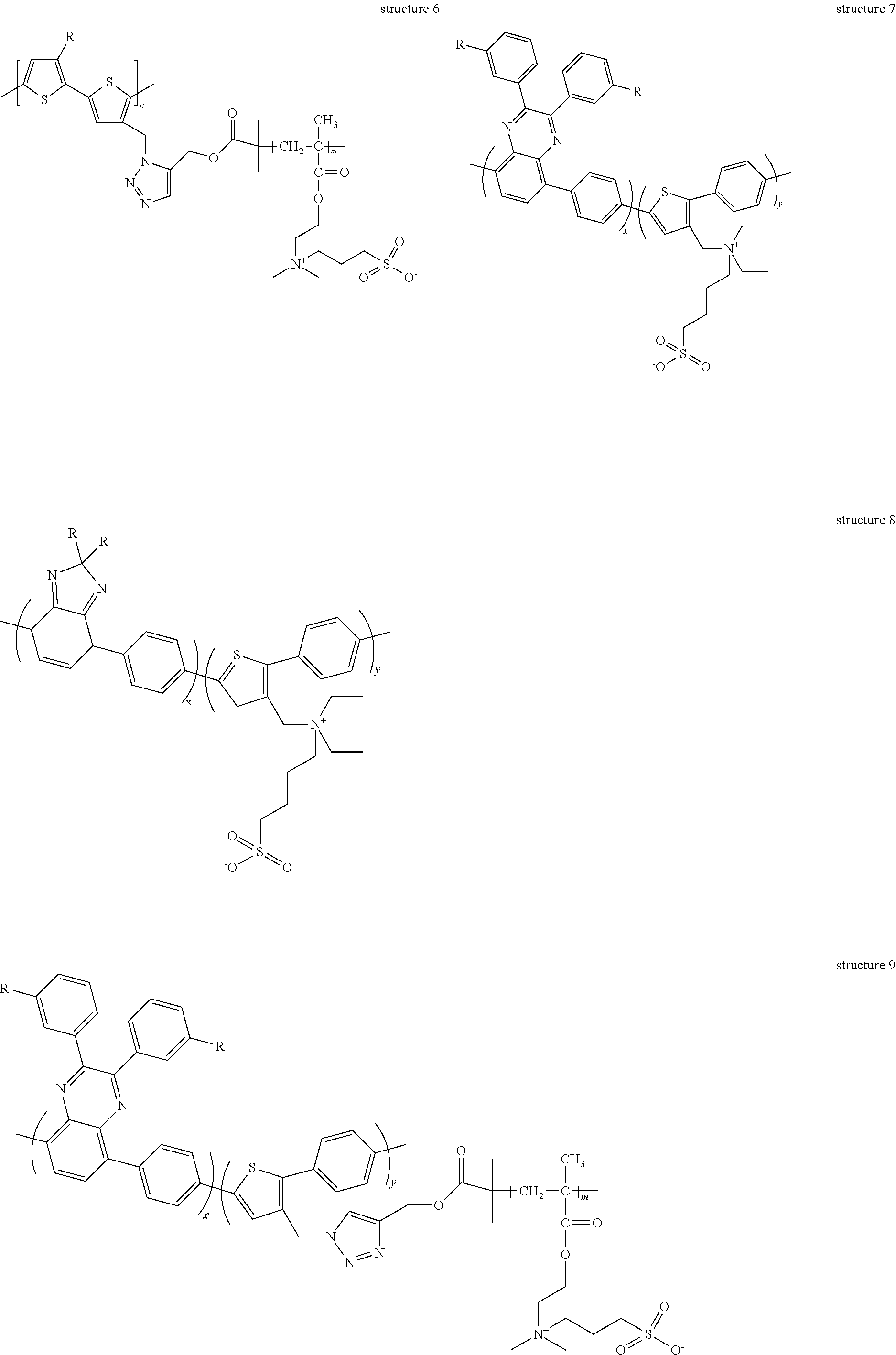 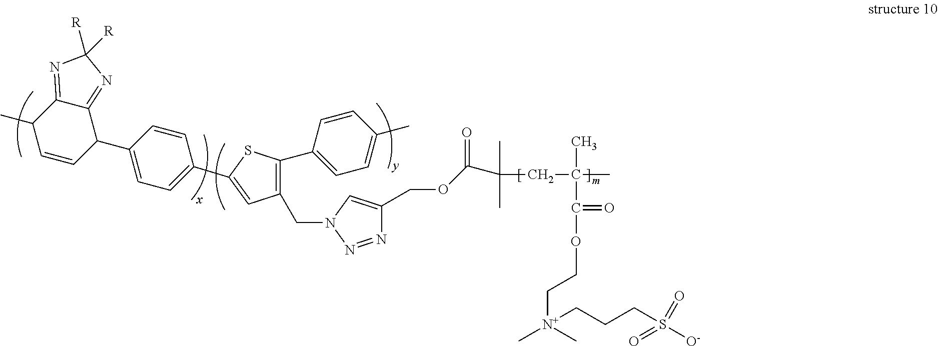
wherein X can be the same or different and is selected from the group consisting of: X=alkyl, alkoxy, 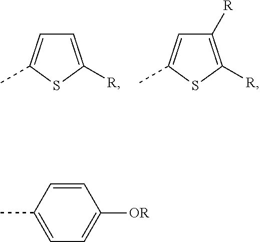
R can be the same or different and is selected from the group consisting of: R: —CₙH₂ₙ₊₁, n>1; linear or branch; or alkoxy
and n, m, x, y≧1

2. A process for preparing the linear zwitterionic conjugated polyelectrolytes (structures 1-3, 7 and 8) of claim 1 wherein the process comprises Suzuki or Stille cross coupling or Grignard metathesis polymerization reaction and subsequent postfunctionalization with cyclic 1,4-butane sultone under conditions such that the polymer structures 1-3 and 7, 8 are formed and the brush-type zwitterionic conjugated polyelectrolytes (structures 4-6, 9 and 10) of claim 1 wherein the process comprises Suzuki or Stille cross coupling or Grignard metathesis polymerization reaction and subsequent postfunctionalization with click reaction between the end alkyne-functionalized zwitterionic poly(2-(dimethylamino)ethyl methacrylate) sulfobetaine (prepared through Atom Transfer Radical Polymerization) under conditions such that the polymer structures 4-6 and 9, 10 are formed

3. A method of preparing a thin layer, the method comprising:
(a) depositing a layer of polymer structures 1-10 of claim 1 by calendaring, screen printing, drop casting, dr blade, spin coating or spraying; and
(b) drying the layer deposited in step (a).
